(19) United States
(12) Patent Application Publication
(10) Pub. No.: US 2007/0114672 A1
(43) Pub. Date: May 24, 2007

(54) Semiconductor device and method of manufacturing the same

(76) Inventors: Tomoko Higashino, Tokyo (JP); Hirotaka Nishizawa, Tokyo (JP); Tamaki Wada, Tokyo (JP); Chuichi Miyazaki, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/583,850

(22) Filed: Oct. 20, 2006

(30) Foreign Application Priority Data
Nov. 18, 2005 (JP) 2005-333542

(51) Int. Cl. H01L 23/52

(52) U.S. Cl. 257/777

(57) ABSTRACT

The miniaturization of the system in package which laminates a plurality of semiconductor chips on a wiring substrate via a die attach film is promoted. In the system in package (SiP) which laminates memory chips and microcomputer chip via die attach film on wiring substrate, by forming metal plate in the chip mounting region of wiring substrate, and mounting memory chip of an undermost layer on this metal plate, the flatness of the chip mounting region of wiring substrate is secured, and die attach film which intervenes between metal plate and memory chip of an undermost layer is made the same quality as die attach film which intervenes between chips (between memory chips and between memory chip and microcomputer chips), and the same thickness.

### CROSS-REFERENCE TO RELATED APPLICATION

The present application claims priority from Japanese patent application No. 2005-333542 filed on Nov. 18, 2005, the content of which is hereby incorporated by reference into this application.

### FIELD OF THE INVENTION

The present invention relates to a semiconductor device and its manufacturing technology, and particularly relates to an effective technology in the application to a thin semiconductor device like the system in package (SiP) which laminated a plurality of semiconductor chips on the wiring substrate.

### DESCRIPTION OF THE BACKGROUND ART

The thin semiconductor device called a system in package (SiP) is provided with the package structure which mounted the microcomputer chip, the memory chip, etc. on the main surface of a wiring substrate, and sealed these semiconductor chips (it may only be hereafter called a chip) by resin.

The wiring substrate of the system in package includes the glass-epoxy-resin plate with which Cu (copper) wiring was formed in the main surface and the internal layer, for example, and a microcomputer chip and a memory chip are electrically connected to the above-mentioned Cu wiring via Au (gold) wire. The Cu wiring of the main surface of a wiring substrate is covered with the thin insulating film called solder resist in order to prevent contamination on the front surface of a wiring, and the short-circuit of wirings.

Many electrodes electrically connected to the above-mentioned Cu wiring are formed in the back surface of a wiring substrate, and the solder bump which forms the external connection terminal of a system in package is connected to each electrode. A system in package is mounted in the mother board of various electronic equipment etc. by doing reflow of the above-mentioned solder bump at the high temperature more than the melt temperature.

Japanese Unexamined Patent Publication No. 2002-93994 (Patent Reference 1) is related with the memory card which laminated a plurality of memory chips on the wiring substrate. This Patent Reference 1 points out the problem that the adhesive property of a chip and a wiring substrate falls, since irregularity of a wiring influences on the surface of solder resist and flatness falls when Cu wiring and solder resist are formed in the chip mounting region of a wiring substrate, when a chip is mounted in a wiring substrate using a paste agent. The technology which secures the flatness of a chip mounting region and strengthens adhesive property of a chip and a wiring substrate by not forming Cu wiring and solder resist in the chip mounting region of a wiring substrate is disclosed as the measures.

[Patent Reference 1] Japanese Unexamined Patent Publication No. 2002-93994

### SUMMARY OF THE INVENTION

In order to mount a microcomputer chip and a memory chip on the wiring substrate of a system in package, where a dicing tape is stuck on the back surface of the semiconductor wafer (only henceforth a wafer) to which the preceding process (wafer process) completed, dicing is performed, and a wafer is divided into a plurality of chips. Next, one piece is peeled at a time from a dicing tape, and these chips are transported on a wiring substrate using the adsorption jig called an adsorption collet. The paste agent (adhesives) is beforehand applied to the chip mounting region of a wiring substrate using the paste coating equipment called a dispenser, and a chip is pasted up on the surface of a wiring substrate via this paste agent.

However, in recent years, in order to realize advanced features and a miniaturization collectively, as for the system in package, stacked package-ization which mounts a plurality of chips in three dimensions on a wiring substrate is advanced. When assembling such a stacked package, in order to suppress the increase in package thickness, it is required that thickness of a chip should be made thin to below 90□m, for example, about 50-60□m.

However, when thickness of a chip is made below 90□m, the problem that a paste agent will creep up from the end portion of a chip to the main surface side, and will cover the front surface of a bonding pad when pasting up a chip on the surface of a wiring substrate via a paste agent will occur. Since the paste agent has viscosity, the chip moves when pasting up a chip on the surface of a wiring substrate, and it is difficult to mount a chip on the surface of a wiring substrate in the state where it is stabilized. Since the thickness of a chip is as thin as below 90□m, the die strength of a chip may become low and a chip crack may be generated in a manufacturing process.

Then, in order to avoid such a problem, the adhesion material of the shape of a film called a die attach film (Die Attach Film) is used instead of a paste agent. Via this die attach film, a chip is pasted up on the surface of a wiring substrate, or pasting up other chips further on a chip is performed.

When using this die attach film, when sticking a dicing tape on the back surface of the wafer which the wafer process completed, the die attach film is first put between the wafer and the dicing tape. And after doing dicing of a wafer and the die attach film simultaneously in this state, the divided chip is peeled from a dicing tape with a die attach film. And after pasting up a chip on the surface of a wiring substrate via a die attach film, a die attach film is heated and adhesives are cured.

When the thickness of a wafer becomes thin, the strength will become weak, and when transporting to a dicing step, there is a possibility that a wafer may break. Therefore, the effect that the strength of a wafer is securable is also acquired by making a die attach film intervene between a wafer and a dicing tape.

However, the present inventor found out that the following problems would occur when assembling a stacked package and it is going to paste up a chip on the surface of a wiring substrate via a die attach film.

As mentioned above, in the stacked package which mounts a plurality of chips in three dimensions on a wiring substrate, it is required that thickness of respective chips should be made thin, for example to about 50-60□m. However, if the thick die attach film was used when pasting up the chip made thin on the surface of a wiring substrate or further laminating the other chip on a chip, since package thickness increases, it is required that thickness of the die attach film which is used should also be made thin according to the number of sheets of the chip to laminate.

However, since the level difference resulting from Cu wiring exists in the main surface of a wiring substrate, irregularity reflecting this level difference exists also on the surface of solder resist. When using the paste agent which is liquider than a die attach film, a paste agent will flow into the recess formed in the main surface of a wiring substrate. Therefore, compared with a die attach film, the flatness of the region which mounts the chip in the main surface of a wiring substrate is securable. On the other hand, since the viscosity of a die attach film is high compared with a paste agent when pasting up a chip on the surface of a wiring substrate and a thin die attach film is used, a cavity (void) occurs between a die attach film and solder resist. As a result, the so-called reflow crack that air and moisture in the above-mentioned cavity expand thermally, and destroys a package when doing reflow of the solder bump which is pasted on the back surface of the wiring substrate is caused.

A thick die attach film is stuck on the back surface of the chip of an undermost layer as the measures, and it is possible to apply pressure strong from the upper part when this chip is mounted on a wiring substrate. Since a die attach film will be embedded without a clearance in the clearance between solder resist and a chip when it does in this way, the generation of a cavity can be suppressed.

However, when a chip is mounted on a wiring substrate and strong pressure is applied on the surface of a chip, there is a possibility that the integrated circuit formed in the chip may receive a damage, or a chip may break. When the resin seal of the chip is done after laminating a plurality of chips, and electrically connecting wiring substrates and these chips with Au wire continuously on a wiring substrate as the measures, it is possible to embed a die attach film without a clearance in the clearance between solder resist and a chip using the heat of resin, and the welding pressure of a metallic mold.

However, by the above-mentioned method, when electrically connecting a chip with a wiring substrate with Au wire, the die attach film which intervenes between both is in un-hardening or a half-hardening state. Therefore, when doing bonding of the Au wire to the bonding pad of a chip, a chip moves slightly to a wiring substrate and the problem that the connection reliability of a bonding pad and Au wire falls occurs.

Thus, although the thin die attach film for example, less than 10□m can also be used between a lower layer chip and the upper chip since flattening of the main surface and back surface of a chip is done when laminating a chip on a wiring substrate using a die attach film, since a thick die attach film must be used between the chip of an undermost layer, and a wiring substrate, the height from the main surface of a wiring substrate to the chip of the top layer becomes large by that part, and the miniaturization of a system in package is hampered.

Since the die attach film made to intervene between chips and the die attach film made to intervene between a chip and a wiring substrate must be made into another specification, the assembling process of a system in package is complicated. As for the thick die attach film made to intervene between a chip and a wiring substrate, since a manufacturing cost is also high compared with a thin die attach film, the manufacturing cost of a system in package also becomes expensive.

A purpose of the present invention is to offer the technology of promoting the miniaturization of the semiconductor device which laminates a plurality of chips on a wiring substrate via a die attach film.

An other purpose of the present invention is to offer the technology which improves the reliability and the manufacturing yield of the semiconductor device which laminates a plurality of chips on a wiring substrate via a die attach film.

Other purposes of the present invention are to offer the technology of reducing the manufacturing cost of the semiconductor device which laminates a plurality of chips on a wiring substrate via a die attach film.

The above-described and the other purposes and novel features of the present invention will become apparent from the description herein and accompanying drawings.

Of the inventions disclosed in the present application, typical ones will next be summarized briefly.

As for a semiconductor device, a plurality of semiconductor chips are laminated via a die attach film over a main surface of a wiring substrate by which a plurality of wirings are formed in the main surface, and resin seal of the semiconductor chips is done, the semiconductor chip of an undermost layer is mounted via the die attach film among the semiconductor chips over a metal plate formed over the main surface of the wiring substrate, and a thickness of the die attach film which intervenes between the semiconductor chip of the undermost layer and the wiring substrate is a same as a thickness of a die attach film which intervenes between a lower layer semiconductor chip and an upper semiconductor chip.

A method of manufacturing a semiconductor device of this invention is a method of manufacturing a semiconductor device which does a resin seal of a plurality of semiconductor chips after laminating the semiconductor chips via a die attach film over a main surface of a wiring substrate by which a plurality of wirings were formed in the main surface, and comprises the steps of: (a) mounting a first semiconductor chip over the main surface of the wiring substrate via a first die attach film; and (b) mounting a second semiconductor chip over the first semiconductor chip via a second die attach film, wherein the first semiconductor chip is mounted via the first die attach film over a metal plate formed over the main surface of the wiring substrate.

Advantages achieved by some of the most typical aspects of the invention disclosed in the present application will be briefly -described below.

By laminating a plurality of chips via a die attach. film on the metal plate formed on the main surface of a wiring substrate, since the flatness of the main surface of a wiring substrate is securable, thickness of the die attach film which intervenes between the chip of an undermost layer and a wiring substrate can be made the same as the thickness of the die attach film which intervenes between a lower layer chip and the upper chip.

### BRIEF DESCRIPTION OF THE DRAWINGS

FIG. 1 is a cross-sectional view of the semiconductor device which is the 1 embodiment of the present invention;

FIG. 2 is a plan view showing the internal configuration of the semiconductor device which is the 1 embodiment of the present invention;

FIG. 3 is a plan view showing the layout of the chip mounted on the wiring substrate of the semiconductor device which is the 1 embodiment of the present invention;

FIG. 4 is a plan view showing the wiring substrate (back surface side) of the semiconductor device which is the 1 embodiment of the present invention;

FIGS. 5 and 6 are plan views of the memory chip mounted in the semiconductor device which is the 1 embodiment of the present invention;

FIG. 7 is a plan view of the microcomputer chip mounted in the semiconductor device which is the 1 embodiment of the present invention;

FIG. 8 is a plan view of the semiconductor wafer used for manufacture of the semiconductor device which is the 1 embodiment of the present invention;

FIG. 9 is a front surface side plan view of a matrix substrate used for manufacture of the semiconductor device which is the 1 embodiment of the present invention;

FIG. 10 is a back surface side plan view of a matrix substrate used for manufacture of the semiconductor device which is the 1 embodiment of the present invention;

FIG. 11 is an outline cross-sectional view of a dicing step showing the manufacturing method of the semiconductor device which is the 1 embodiment of the present invention;

FIG. 12 is an outline perspective view of a dicing step showing the manufacturing method of the memory card which is the 1 embodiment of the present invention;

FIG. 13 is an outline cross-sectional view of a dicing step showing the manufacturing method of the memory card which is the 1 embodiment of the present invention;

FIG. 14 A is a plan view of the memory chip obtained by dicing, and FIG. 14 B is a cross-sectional view of the memory chip obtained by dicing;

FIGS. 15 and 16 are schematic diagrams of the pickup device in which the manufacturing method of the semiconductor device which is the 1 embodiment of the present invention is shown;

FIG. 17 is a principal part plan view of a matrix substrate showing the manufacturing method of the semiconductor device which is the 1 embodiment of the present invention;

FIG. 18 is a principal part cross-sectional view of a matrix substrate showing the manufacturing method of the semiconductor device which is the 1 embodiment of the present invention;

FIG. 19 is a principal part plan view of a matrix substrate showing the manufacturing method of the semiconductor device which is the 1 embodiment of the present invention;

FIG. 20 is a principal part cross-sectional view of a matrix substrate showing the manufacturing method of the semiconductor device which is the 1 embodiment of the present invention;

FIG. 21 is a principal part plan view of a matrix substrate showing the manufacturing method of the semiconductor device which is the 1 embodiment of the present invention;

FIGS. 22 and 23 are principal part cross-sectional views of a matrix substrate showing the manufacturing method of the semiconductor device which is the 1 embodiment of the present invention; and

FIG. 24 is a principal part cross-sectional view of the semiconductor device which are other embodiments of the present invention.

### DETAILED DESCRIPTION OF THE PREFERRED EMBODIMENTS

Hereafter, embodiments of the invention are explained in detail based on drawings. In all the drawings for describing the embodiments, members of a like function will be identified by like reference numerals and overlapping descriptions will be omitted.

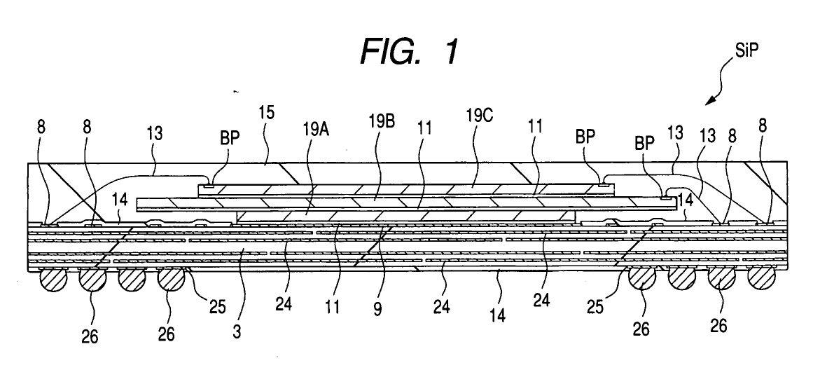

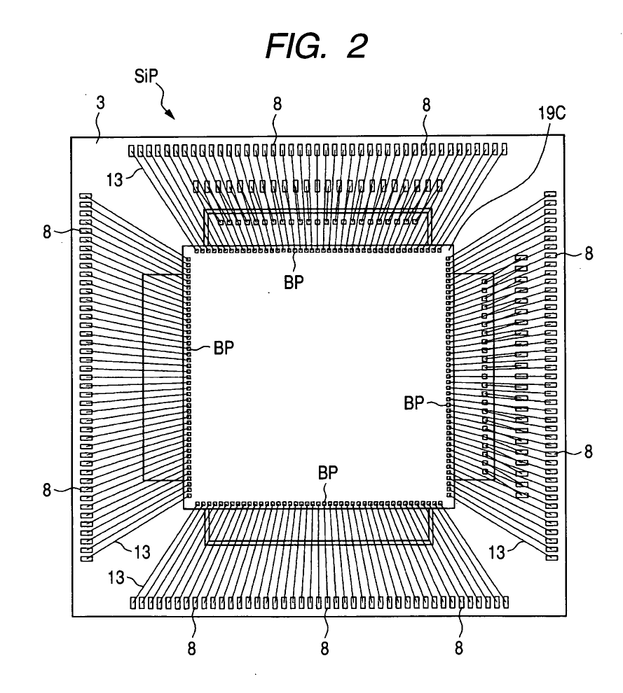

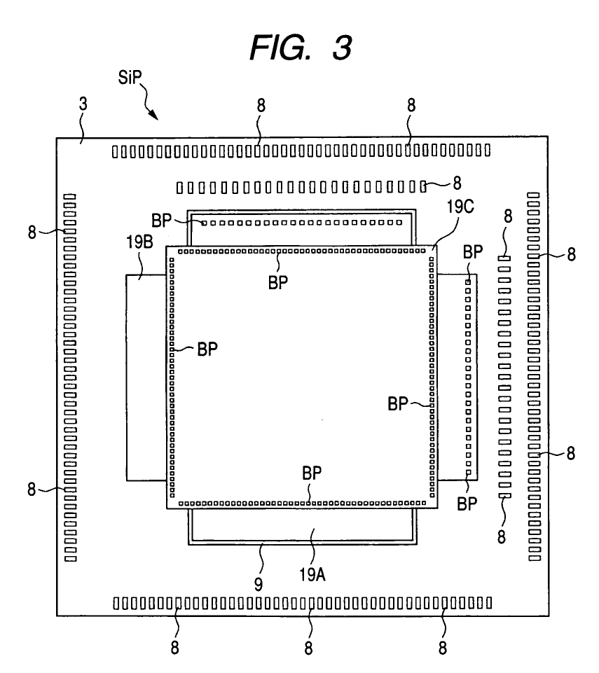

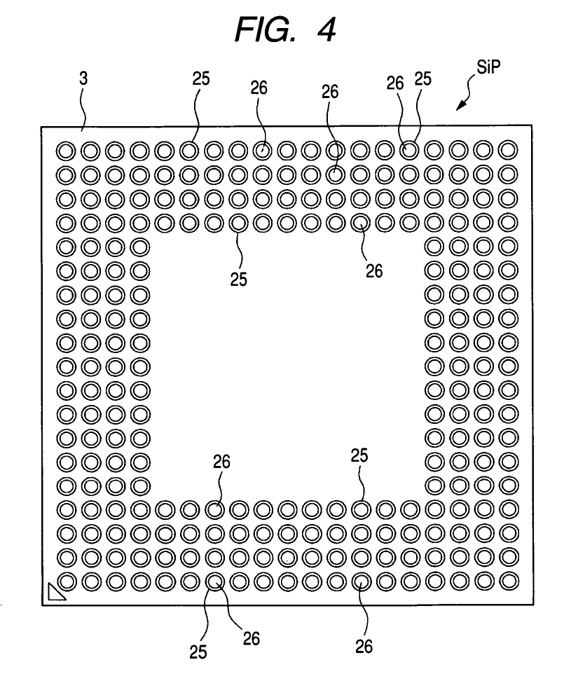

FIG. 1 is a cross-sectional view showing the semiconductor device of this embodiment, FIG. 2 is a plan view showing the internal configuration of this semiconductor device, FIG. 3 is a plan view showing the layout of the chip mounted on the wiring substrate of this semiconductor device, and FIG. 4 is a plan view showing the back surface of the wiring substrate of this semiconductor device.

The semiconductor device of this embodiment is the system in package (SiP) which piles up and mounts three chips (memory chips 19A and 19B and microcomputer chip 19C) on the main surface of wiring substrate 3, and which sealed these chips (memory chips 19A and 19B and microcomputer chip 19C) with mold resin 15.

Wiring substrate 3 is a multilayer interconnection substrate formed using general-purpose resin like glass epoxy resin as a core. Wiring (wiring pattern) 8 and metal plate (metal layer) 9 which etched and formed thin Cu (copper) foil of about 10□m-15□m in thickness are formed in the main surface. Ni (nickel) plating is performed to the front surface of Cu foil which forms wiring 8 and metal plate 9, and Au plating is further performed on Ni plated layer to a part of wiring 8 (the region where bonding of the Au (gold) wire is done, electrode). Metal plate 9 is functioning as a part of wiring 8, for example, a reference potential plate.

On metal plate 9, memory chip 19A is mounted via die attach film 11. Here, the bonding strength of die attach film 11 and Au plating is lower than the bonding strength of die attach film 11 and Ni plated layer. Therefore, as described above, only Ni plating is performed to the front surface of Cu foil which forms metal plate 9, and Au plating is not performed on Ni plated layer. On this memory chip 19A, second memory chip 19B is mounted via die attach film 11, and microcomputer chip 19C is mounted via die attach film 11 on second memory chip 19B. Metal plate 9 is formed in the flat region of one side of wiring substrate 3 in order to make flat the front surface (region in which a chip is mounted). That is, other conductor layers etc. are not formed between metal plate 9, and wiring substrate 3 of the lower part. The area of metal plate 9 is slightly larger than the area of memory chip 19A mounted on it. This is because the problem that a position drift of some occurred when a chip is mounted was taken into consideration. Solder resist (an insulating film, a protective film) 14 is formed in the circumference of metal plate 9, and height differs from the front surface of metal plate 9. That is, the height of the front surface of metal plate 9 and the front surface of solder resist 14 differs. Therefore, if the area of metal plate 9 and the area of memory chip 19A are formed in the same size, it is mounted so that a part of memory chip 19A may overlap in plan view with a part of solder resist 14 by the position drift at the time of mounting. Hereby, a cavity will occur between die attach film 11 and metal plate 9. However, in this embodiment, since the area of metal plate 9 is formed more greatly than the area of memory chip 19A to mount, it is possible to certainly mount in the region of metal plate 9.

All of die attach film 11 which intervenes between metal plate 9 and memory chip 19A of an undermost layer, die attach film 11 which intervenes between memory chip 19A and memory chip 19B, and die attach films 11 that intervene between memory chip 19B and microcomputer chip 19C include adhesion material of the same quality, and they have the same thickness (below 25□m, for example, about 5□m).

SRAM (Static Random Access Memory) is formed in the main surface of memory chip 19A of an undermost layer among the three above-mentioned chips (memory chips 19A and 19B and microcomputer chip 19C). The flash memory is formed in the main surface of memory chip 19B. The high-speed microprocessor (MPU: microprocessor unit) is formed in microcomputer chip 19C of the top layer.

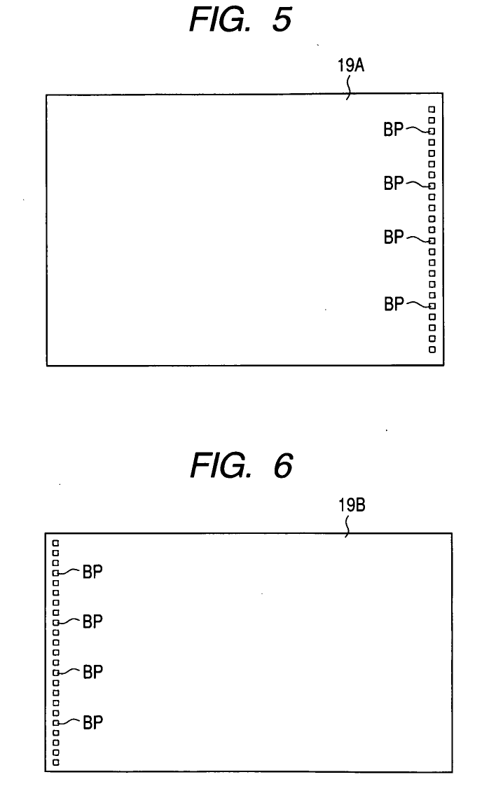

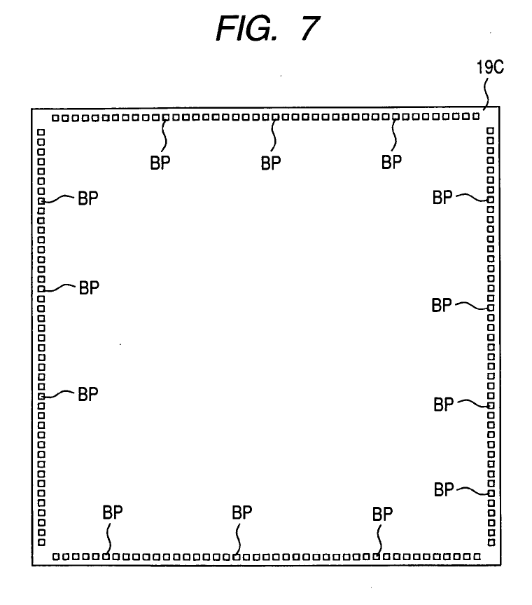

As shown in FIG. 5, a plurality of bonding pads BP are formed in the main surface of memory chip 19A in which SRAM was formed at the single line along one side of them. As shown in FIG. 6, a plurality of bonding pads BP are formed in the main surface of memory chip 19B in which the flash memory was formed at the single line along one side of them. As shown in FIG. 7, a plurality of bonding pads BP are formed in the main surface of microcomputer chip 19C in which the high-speed microprocessor was formed at the single line along the four sides.

Bonding pad BP of memory chip 19A and wiring 8 (a part of wiring 8, an electrode) of wiring substrate 3 are electrically connected via Au wire 13. Bonding pad BP of memory chip 19B and wiring 8 of wiring substrate 3 are electrically connected via Au wire 13. Bonding pad BP of microcomputer chip 19C and wiring 8 of wiring substrate 3 are electrically connected via Au wire 13. That is, three chips (memory chips 19A and 19B and microcomputer chip 19C) are electrically connected to wiring substrate 3 by the wire-bonding system. A part of wiring 8 formed in one side of wiring substrate 3 is illustrated by FIG. 2 and FIG. 3. The main surface of wiring substrate 3 is covered with mold resin 15 for protecting the three above-mentioned chips (memory chips 19A and 19B and microcomputer chip 19C), Au wire 13, etc. Mold resin 15 is formed by epoxy system resin having included fillers, such as silica.

For example, internal wiring 24 of about four layers and the via hole which is not illustrated are formed in the inside of wiring substrate 3. 240 electrodes 25 electrically connected to wiring 8 via internal wiring 24 and a via hole are formed in the back surface of wiring substrate 3. As well as the wiring 8 and metal plate 9, internal wiring 24 and electrode 25 are formed by etching Cu foil, and Au plating is performed to the front surface of electrode 25 via Ni plating.

Solder bump 26 which forms the external connection terminal of a system in package (SiP) is connected to electrode 25 formed in the back surface of wiring substrate 3. A system in package (SiP) is mounted in the mother board of various electronic equipment etc. via these solder bumps 26. That is, wiring substrate 3 functions as a relay board (interposer) at the time of mounting the three above-mentioned chips (memory chips 19A and 19B and microcomputer chip 19C) in a mother board etc.

Solder resist 14 for preventing contamination of wiring 8 and the short-circuit of wiring 8 each other is formed in the main surface of wiring substrate 3. Solder resist 14 is an insulation film which includes polyimide resin etc. and whose thickness is 20 μm grade, and is formed throughout the main surface of wiring substrate 3 except for a part of wiring 8 (region where bonding of the Au wire 13 is done), and the front surface of metal plate 9. Similarly, solder resist 14 is formed in the back surface of wiring substrate 3 except for the front surface of electrode 25.

Thus, the system in package (SiP) of this embodiment has the BGA (Ball Grid Array) structure of 240 pins which laminated three chips (memory chips 19A and 19B and microcomputer chip 19C) on wiring substrate 3, and formed the system with these three chips.

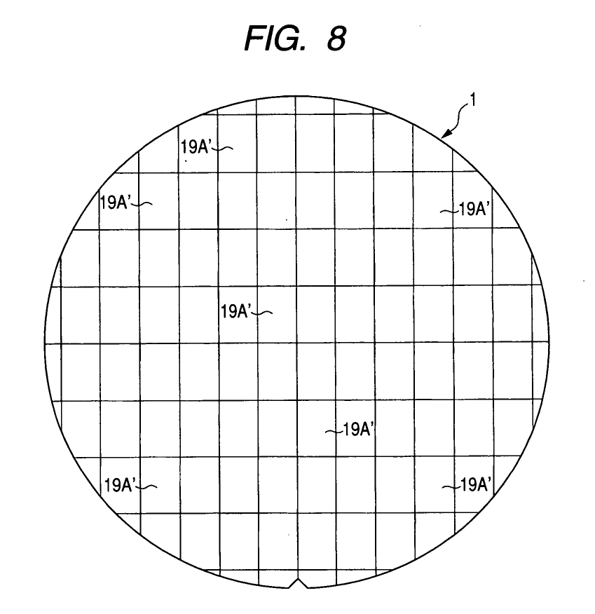

FIG. 8 is a plan view of wafer 1 used for manufacture of the above-mentioned system in package (SiP). Wafer 1 shown in FIG. 8 includes single crystal silicon of 300 mm in diameter and 7500□m-800□m in thickness, and the main surface is divided in a lattice manner by a plurality of chip area 19A′. And SRAM is formed in each chip area 19A′ of the well-known semiconductor manufacturing process.

The above-mentioned semiconductor manufacturing process includes a film formation step, the ion implantation step of an impurity, photolithography operation, an etching step, a metallizing step, a cleaning process, the test step between each step, etc. In the last process of this semiconductor manufacturing process, the good or bad of chip area 19A′ of wafer 1 is judged by the electrical test using a probe.

In order to manufacture a system in package (SiP), the second wafer with which the flash memory was formed and the third wafer with which the microcomputer was formed other than the above-mentioned wafer 1 with which SRAM was formed are prepared, but illustration is omitted about these wafers.

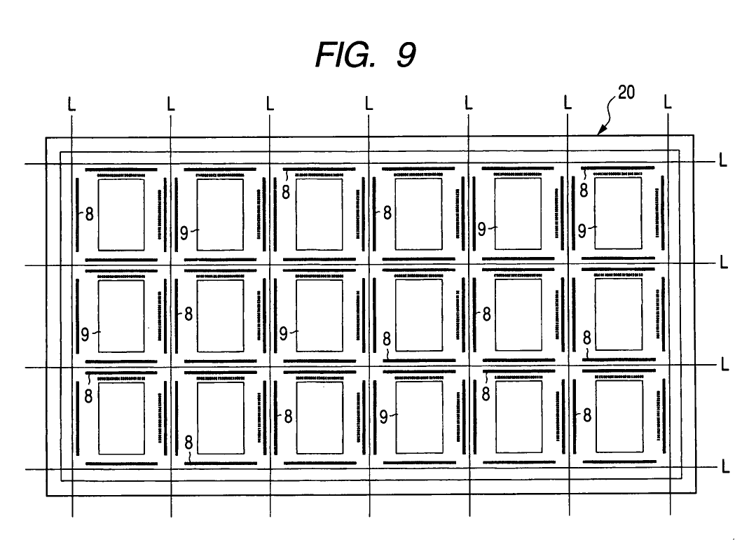

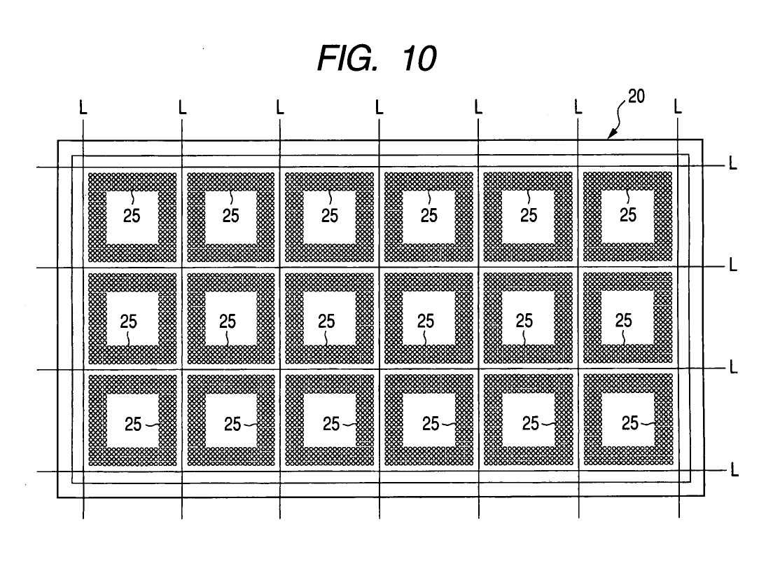

FIG. 9 and FIG. 10 are plan views of matrix substrate 20 used for manufacture of the above-mentioned system in package (SiP) (FIG. 9 is a front surface side, FIG. 10 is a back surface side). In this matrix substrate 20, it has the structure where a conductor pattern called wiring 8, metal plate 9, and electrode 25 of wiring substrate 3 mentioned above was repeatedly formed in the longitudinal direction and the horizontal direction. That is, matrix substrate 20 is a substrate used as the parent of the wiring substrate 3, and a plurality of wiring substrates 3 are obtained by cutting (dicing) this matrix substrate 20 in a lattice manner along dicing line L shown in FIG. 9 and FIG. 10. For example, the long side direction is divided in the wiring substrate region which is 6 blocks, matrix substrate 20 shown in a drawing is divided in the wiring substrate region whose short side direction is 3 blocks, and 3×6=18 piece wiring substrate 3 is obtained.

In order to manufacture a system in package (SiP), the thickness is made thin to below 90□m, for example about 50□m-60□m by polishing first the back surface of wafer 1 shown in the FIG. 8. In order to polish the back surface of wafer 1, the back-grinding tape for integrated circuit protection (not shown) is stuck on the main surface of wafer 1, and a back surface side is ground by a grinder, then, the damaged layer generated by grinding is removed by methods, such as wet etching, dry polishing, and plasma etching. Similarly, those thickness is made thin to below 90 μm, for example, about 50 μm˜60 μm, by polishing the back surface of the second wafer with which the flash memory was formed, and the back surface of the third wafer in which the microcomputer was formed, respectively.

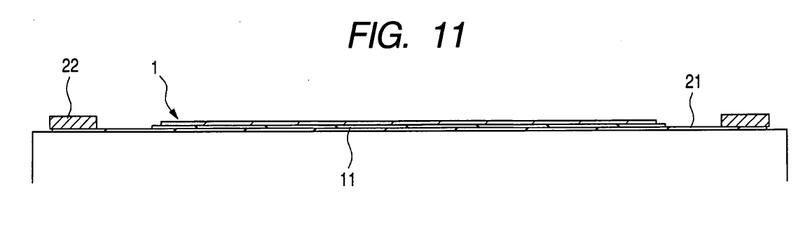

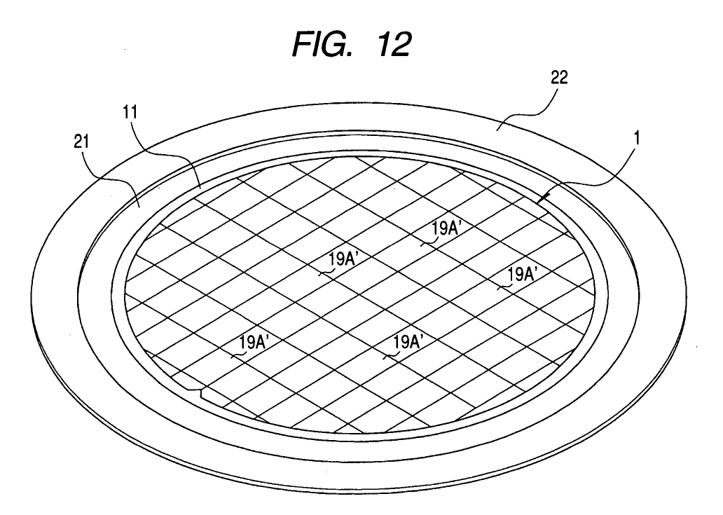

Next, as shown in FIG. 11 and FIG. 12, die attach film 11 is stuck on the back surface of wafer 1, and dicing tape 21 is further stuck on the back surface of die attach film 11. Wafer ring 22 is stuck on the periphery of dicing tape 21. Dicing tape 21 is an insulating adhesive tape about thickness 90 μm˜120 μm which applied the ultraviolet curing type pressure-sensitive adhesive etc. to one side of the tape base material which includes polyolefine (PO), polyvinyl chloride (PVC), etc., and gave adhesive property. Wafer ring 22 is a jig for holding dicing tape 21 and giving tension horizontal to dicing tape 21.

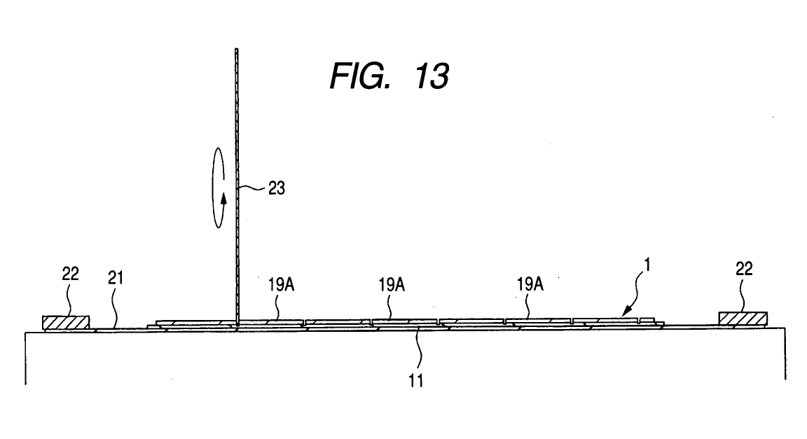

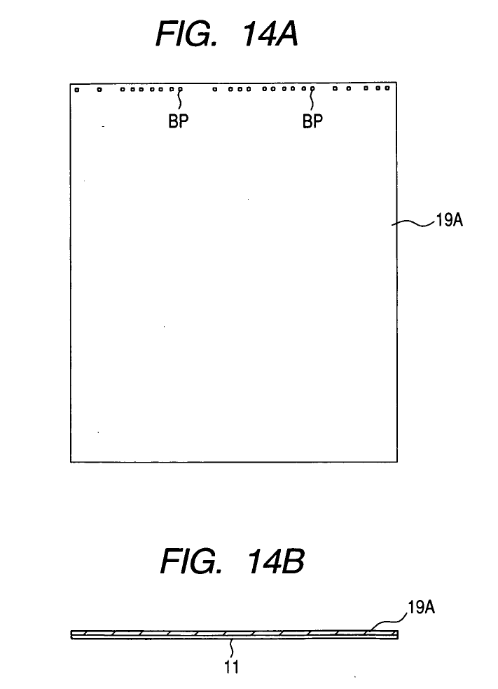

Next, as shown in FIG. 13, dicing of wafer 1 and the die attach film 11 is done using dicing blade 23, and each of chip area 19A′ is individually separated. Hereby, as shown in FIGS. 14A and 14B, memory chip 19A in which die attach film 11 adhered to the back surface is obtained. Although illustration is omitted, memory chip 19B and microcomputer chip 19C with which die attach film 11 adhered to the back surface are obtained by performing the processing same also about the second wafer with which the flash memory was formed, and the third wafer with which the microcomputer was formed as the above.

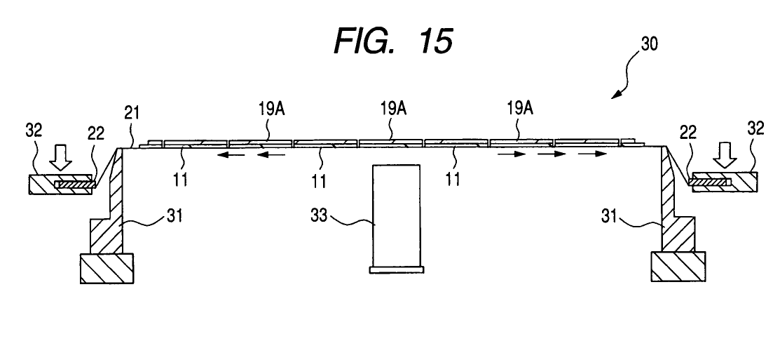

Next, as shown in FIG. 15, the above-mentioned dicing tape 21 on which a plurality of memory chips 19A pasted up is positioned horizontally on retaining ring 31 of pickup device 30, and wafer ring 22 adhered on the periphery of dicing tape 21 is held in expand ring 32. Inside retaining ring 31, adsorption piece 33 for thrusting up memory chip 19A is arranged. Then, dicing tape 21 is irradiated with UV rays. When it does in this way, the adhesive applied to dicing tape 21 can harden, adhesive power can decline, and die attach film 11 can be easily peeled from dicing tape 21.

Next, wafer ring 22 adhered on the periphery of dicing tape 21 is depressed below by descending expand ring 32 of pickup device 30. When it does in this way, dicing tape 21 will be extended in response to the strong tension which goes to a periphery from the central part without slackening horizontally.

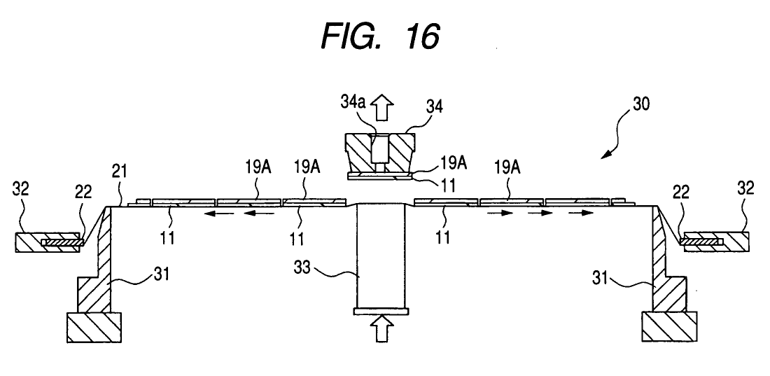

Next, as shown in FIG. 16, adsorption piece 33 to which it was made to move under the memory chip 19A which is the object of peeling is thrust up, and memory chip 19A, and die attach film 11 adhering to the back surface are peeled from dicing tape 21 using adsorption collet 34. Adsorption opening 34a with which an inside is decompressed is formed in the central part of the bottom of adsorption collet 34, and selectively, only one memory chip 19A which is the object of peeling is adsorbed, and can be held now.

Thus, memory chip 19A which peeled from dicing tape 21 with die attach film 11 is adsorbed and held at adsorption collet 34, and is transported by the next step (pellet attachment step). And when adsorption collet 34 which transported memory chip 19A to the next step returns to pickup device 30, according to the above-mentioned procedure, the following memory chip 19A will peel from dicing tape 21. Henceforth, according to the same procedure, memory chip 19A peels one piece at a time from dicing tape 21. Although illustration is omitted, by using the above-mentioned pickup device 30, it peels memory chip 19B from the second wafer with which the flash memory was formed, and peels microcomputer chip 19C from the third wafer with which the microcomputer was formed.

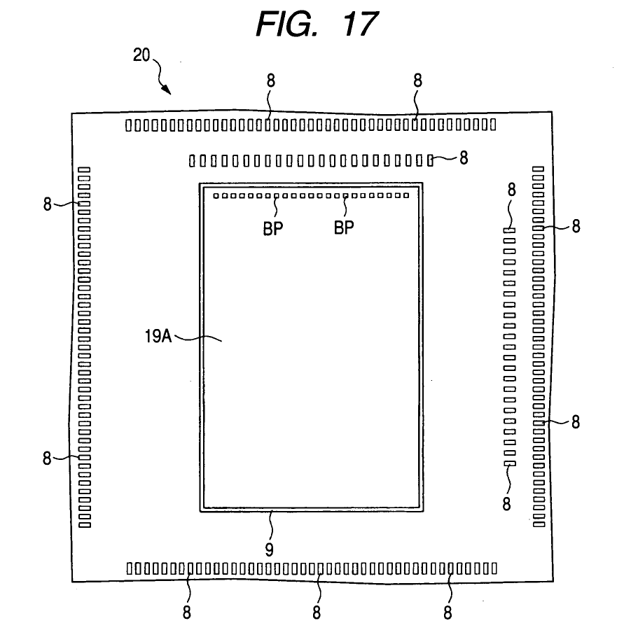

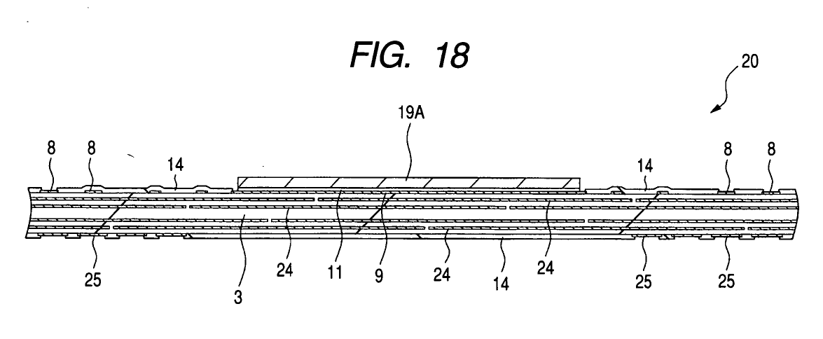

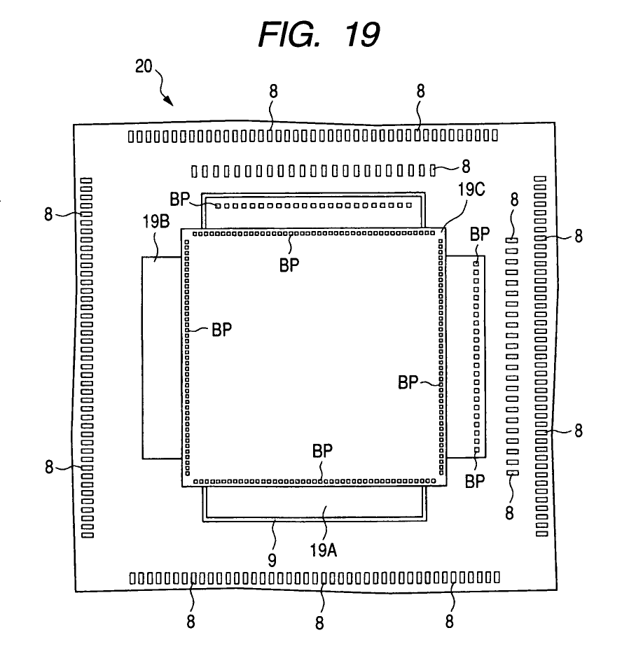

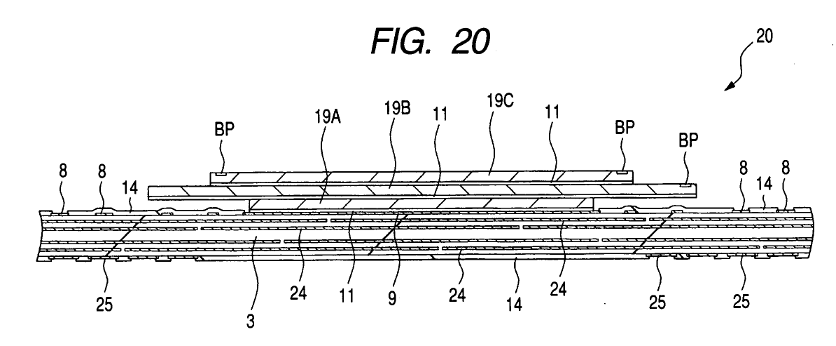

Memory chip 19A transported by the pellet attachment step is mounted on metal plate 9 of matrix substrate 20 via die attach film 11, as shown in FIG. 17 (principal part plan view of matrix substrate 20), and FIG. 18 (principal part cross-sectional view of matrix substrate 20). Next, as shown in FIG. 19 and FIG. 20, second memory chip 19B is mounted via die attach film 11 on memory chip 19A, and microcomputer chip 19C is mounted via die attach film 11 on second memory chip 19B.

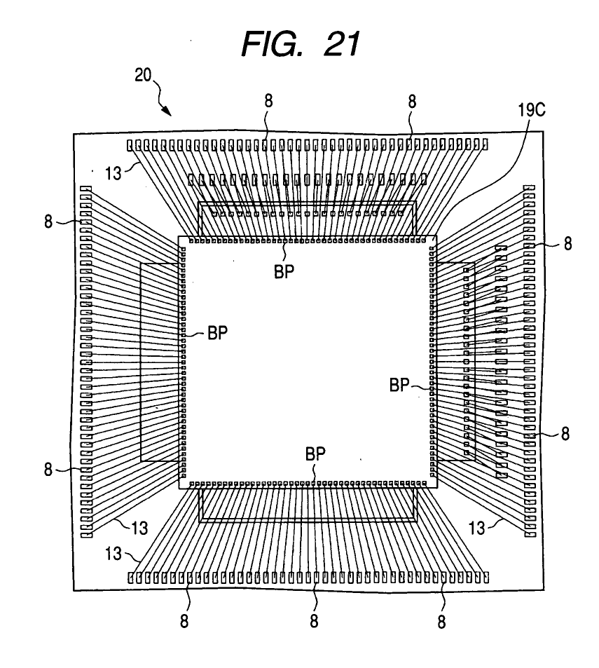

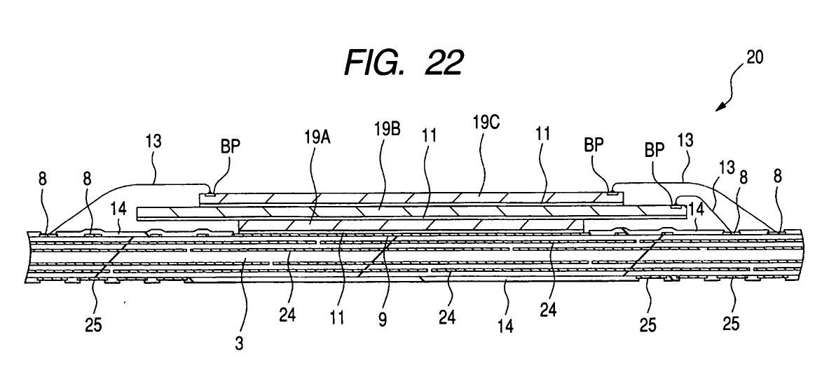

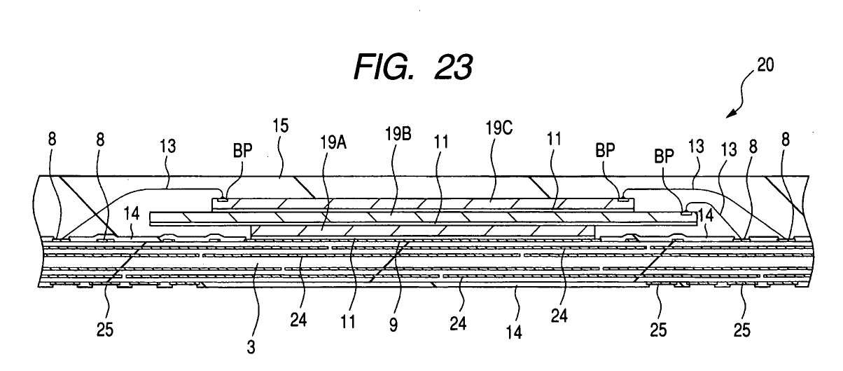

Next, after heat-treating matrix substrate 20 and doing complete cure of all the die attach films 11, as shown in FIG. 21 and FIG. 22, bonding pad BP of three chips (memory chips 19A and 19B and microcomputer chip 19C) and wiring 8 of matrix substrate 20 are electrically connected with Au wire 13. Then, as shown in FIG. 23, the whole main surface of matrix substrate 20 is sealed with mold resin 15.

Then, by connecting solder bump 26 to electrode 25 of matrix substrate 20, and cutting mold resin 15 and matrix substrate 20 in a lattice manner along dicing line L shown in the FIG. 9 and FIG. 10 (dicing), the system in package (SiP) of this embodiment shown in the FIG. 1-FIG. 4 is completed.

Thus, when three chips (memory chips 19A and 19B and microcomputer chip 19C) are laminated via die attach film 11 in this embodiment on wiring substrate 3, metal plate 9 is formed in the chip mounting region of wiring substrate 3, and memory chip 19A of an undermost layer is mounted on this metal plate 9. Since the flatness of the chip mounting region of wiring substrate 3 is securable by this, even if it makes thin thickness of die attach film 11 which intervenes between metal plate 9 and memory chip 19A of an undermost layer to below 10□m, for example, about 5□m, a cavity (void) does not occur in the lower layer of this die attach film 11.

Hereby, when doing reflow of the solder bump 26 which is pasted on the back surface of wiring substrate 3, the generation of a reflow crack can be suppressed and the reliability of a system in package (SiP) improves. Since die attach film 11 stuck on each back surface of three chips (memory chips 19A and 19B and microcomputer chip 19C) can be altogether made thin, the height from the main surface of wiring substrate 3 to microcomputer chip 19C of the top layer can be reduced, and the miniaturization of a system in package (SiP) can be promoted.

Since die attach film 11 stuck on each back surface of three chips (memory chips 19A and 19B and microcomputer chip 19C) is made to the same specification, the assembling process of a system in package (SiP) can be simplified. Since thickness of all the die attach films 11 can be made thin, the manufacturing cost of die attach film 11 can be lowered, and the manufacturing cost of a system in package (SiP) can be reduced.

Since memory chip 19A does not move to wiring substrate 3 at the time of wire bonding by doing the complete cure of all the die attach films 11 in advance of a wire-bonding step, the connection reliability of bonding pad BP and Au wire 13 improves.

By giving the function as a wiring which supplies reference potential (GND), for example to metal plate 9 formed in the chip mounting region of wiring substrate 3, the flexibility of a wiring design improves compared with the case where the metal plate which does not have a function as a wiring is formed in the chip mounting region of wiring substrate 3.

In the foregoing, the present invention accomplished by the present inventors is concretely explained based on above embodiments, but the present invention is not limited by the above embodiments, but variations and modifications may be made, of course, in various ways in the limit that does not deviate from the gist of the invention.

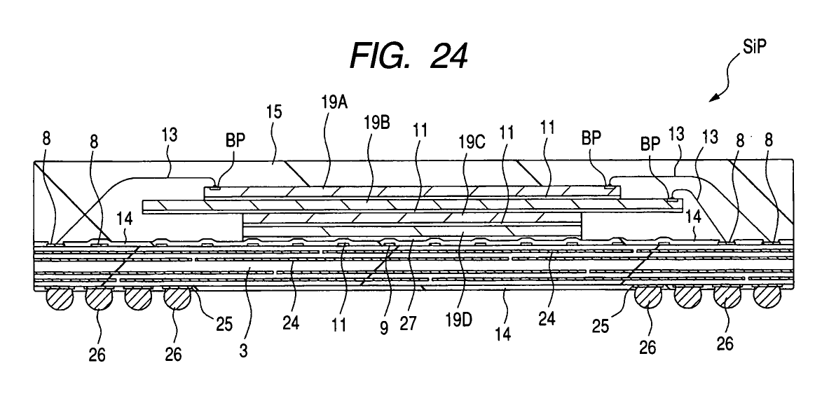

Although memory chip 19A was mounted in the embodiment on metal plate 9 formed in the chip mounting region of wiring substrate 3, For example, as shown in FIG. 24, dummy chip (chip with which the integrated circuit is not formed) 19D may be mounted in the chip mounting region of wiring substrate 3, and memory chip 19A may be mounted in the upper part via die attach film 11.

This dummy chip 19D is a silicon chip obtained by doing dicing of the wafer which does not form an integrated circuit. Although the height from the main surface of wiring substrate 3 to microcomputer chip 19C of the top layer increases when dummy chip 19D is made to intervene between wiring substrate 3 and memory chip 19A, since it becomes possible to form wiring 8 also in the chip mounting region of wiring substrate 3, the flexibility of a wiring design improves.

When wiring 8 is formed in the chip mounting region of wiring substrate 3 and the front surface is covered with solder resist 14, irregularity occurs on the front surface of solder resist 14. Therefore, in order to prevent a cavity (void) occurring between dummy chip 19D and solder resist 14, by pasting up dummy chip 19D on solder resist 14 using die attach film 27 thicker than the die attach film 11, and applying strong pressure from the upper part, die attach film 27 is embedded without a clearance in the clearance between solder resist 14 and dummy chip 19D. In this case, since the integrated circuit is not formed in dummy chip 19D, it is convenient even if it applies pressure strong against the front surface.

Although the system in package which laminated three chips on the wiring substrate was exemplified in the embodiment, of course, the number of chips and the kind of chip which are laminated on a wiring substrate can be arbitrarily changed according to a system.

The present invention is effective technology applying to a thin semiconductor device like the system in package which laminated a plurality of chips on the wiring substrate.

What is claimed is:

1. A semiconductor device with which a plurality of semiconductor chips are stacked via a die attach film over a main surface of a wiring substrate by which a plurality of wirings are formed in the main surface, and resin seal of the semiconductor chips is done, wherein
the semiconductor chip of an undermost layer among the plurality of semiconductor chips is mounted over a metal plate formed over the main surface of the wiring substrate via the die attach film; and
a thickness of the die attach film which intervenes between the semiconductor chip of the undermost layer and the wiring substrate is the same as a thickness of a die attach film which intervenes between a lower layer semiconductor chip and an upper semiconductor chip.

2. A semiconductor device according to claim 1, wherein
a thickness of the die attach film is less than or equal to 25□m.

3. A semiconductor device according to claim 1, wherein
the metal plate is functioning as a part of the wirings.

4. A semiconductor device according to claim 1, wherein
the semiconductor chips include two or more kinds of semiconductor chips with which a mutually different integrated circuit was formed.

5. A semiconductor device according to claim 1, wherein
a plurality of electrodes electrically connected to the wirings are formed over a back surface of the wiring substrate, and a solder bump which forms an external connection terminal is connected to each of the electrodes.

6. A semiconductor device according to claim 1, wherein
the memory chips are electrically connected to the wiring via a metal wire.

7. A semiconductor device with which a plurality of semiconductor chips are laminated via a die attach film over a main surface of a wiring substrate by which a plurality of wirings are formed in the main surface, and resin seal of the semiconductor chips is done, wherein
a semiconductor chip of an undermost layer is mounted via the die attach film among the semiconductor chips over a dummy chip formed over the main surface of the wiring substrate.

8. A semiconductor device according to claim 7, wherein
a thickness of the die attach film which intervenes between the semiconductor chip of an undermost layer and the dummy chip is a same as a thickness of a die attach film which intervenes between a lower layer semiconductor chip and an upper semiconductor chip.

9. A semiconductor device according to claim 7, wherein
a part of the wirings is formed in a lower part of the dummy chip.

10. A semiconductor device according to claim 7, wherein
a thickness of the die attach film is less than or equal to 25□m.

11. A semiconductor device according to claim 7, wherein
the semiconductor chips include two or more kinds of semiconductor chips with which a mutually different integrated circuit was formed.

12. A semiconductor device according to claim 7, wherein
a plurality of electrodes electrically connected to the wirings are formed over a back surface of the wiring substrate, and a solder bump which forms an external connection terminal is connected to each of the electrodes.

13. A method of manufacturing a semiconductor device which does a resin seal of a plurality of semiconductor chips after laminating the semiconductor chips via a die attach film over a main surface of a wiring substrate by which a plurality of wirings were formed in the main surface, comprising the steps of:
(a) mounting a first semiconductor chip over the main surface of the wiring substrate via a first die attach film; and
(b) mounting a second semiconductor chip over the first semiconductor chip via a second die attach film;
wherein the first semiconductor chip is mounted over a metal plate formed over the main surface of the wiring substrate via the first die attach film.

14. A method of manufacturing a semiconductor device according to claim 13, wherein
a thickness of the first and the second die attach film is less than or equal to 25□m.

15. A method of manufacturing a semiconductor device according to claim 13, wherein
the metal plate is functioning as a part of the wirings.

16. A method of manufacturing a semiconductor device according to claim 13, wherein
the first and the second semiconductor chips are electrically connected to the wiring via a metal wire.

17. A method of manufacturing a semiconductor device according to claim 13, wherein
the semiconductor chips include two or more kinds of semiconductor chips with which a mutually different integrated circuit was formed.

18. A method of manufacturing a semiconductor device according to claim 13, wherein
a thickness of the first and the second die attach film is a same.

19. A method of manufacturing a semiconductor device according to claim 13, wherein
a plurality of electrodes electrically connected to the wirings are formed in a back surface of the wiring substrate, and a step which connects a solder bump to each of the electrodes after the step (b) is included further.

20. A method of manufacturing a semiconductor device which does a resin seal of a plurality of semiconductor chips after laminating the semiconductor chips via a die attach film over a main surface of a wiring substrate by which a plurality of wirings were formed in the main surface, comprising the steps of:
(a) mounting a dummy chip over the main surface of the wiring substrate;
(b) mounting a first semiconductor chip over the dummy chip a first die attach film; and
(c) mounting a second semiconductor chip over the first semiconductor chip via a second die attach film.

21. A method of manufacturing a semiconductor device according to claim 20, wherein
a thickness of the first and the second die attach film is less than or equal to 25□m.

22. A method of manufacturing a semiconductor device according to claim 20, wherein
a thickness of the first and the second die attach film is a same.

23. A method of manufacturing a semiconductor device according to claim 20, wherein
the first and the second semiconductor chips are electrically connected to the wiring via a metal wire.

24. A method of manufacturing a semiconductor device according to claim 20, wherein
a plurality of electrodes electrically connected to the wirings are formed over a back surface of the wiring substrate, and a step which connects a solder bump to each of the electrodes after the step (c) is included further.
